(19) United States
(12) Patent Application Publication
(10) Pub. No.: US 2021/0237079 A1
(43) Pub. Date: Aug. 5, 2021

(54) Device with Flow Features for Sample Processing and Method of Use

(71) Applicant: Ontera Inc., Santa Cruz, CA (US)

(72) Inventors: Erik Henry Tews, Santa Cruz, CA (US); Reto Stamm, Santa Cruz, CA (US); Jeffrey William Reed, Santa Cruz, CA (US)

(21) Appl. No.: 17/133,163

(22) Filed: Dec. 23, 2020

Related U.S. Application Data
(60) Provisional application No. 62/968,281, filed on Jan. 31, 2020.

(51) Int. Cl. B01L 3/00; B81B 1/00

(52) U.S. Cl. CPC B01L 3/502761; B01L 2200/0689; B81B 1/006; B81B 2201/05; B81B 2203/033; B81B 2203/0338; B01L 2300/0819; B01L 2300/123; B01L 2300/16; B01L 2200/10; B01L 2200/0652; B01L 2400/084; B01L 2200/0684; B01L 2200/087; B81B 1/002

(57) ABSTRACT

A system for characterization and counting of molecules and/or polymers includes: a base substrate; an electrode layer configured to route one or more electrodes for applying; a chip 130 coupled to the electrode layer and configured to mate with a recessed portion of the base substrate; a sealing layer positioned adjacent to the electrode layer; a second substrate positioned adjacent to the sealing layer; and a set of fasteners coupling the second substrate, the sealing layer, the electrode layer, the chip, and the base substrate together as an assembly. Embodiments of the system can be used for molecular quantification, sizing, and characterization of DNA, RNA, and polymers, as well as characterization of macromolecular interactions (e.g., DNA-protein interactions, RNA-protein interactions, protein-protein interactions). Methods of manufacturing and applications of the system are also described.

### CROSS REFERENCE TO RELATED APPLICATIONS

This application claims priority to U.S. Provisional Application No. 62/968,281 filed on Jan. 31, 2020. The content of the above referenced application is incorporated by reference in its entirety.

### BACKGROUND

The ability to rapidly process biological samples and analyze molecular components of the sample (e.g., target and non-target molecular components) in a manner that does not place significant burden on an operator is important for many applications. In particular, applications in point-of-care diagnostics significantly benefit from technologies that have high performance and are easy to use. Additionally or alternatively, applications in detection of genetically modified crops, through interrogation of DNA or proteins, benefit from technologies that can be implemented rapidly at a site of sample acquisition, while accurately conveying results.

As such, point-of-care, in-field use, and other applications of use associated with biological sample processing can introduce design constraints warranting new technologies for rapid and accurate detection of targets from samples.

### SUMMARY

Embodiments of the system(s) and method(s) described cover a device (e.g., test strip) including flow features (e.g., a microfluidic channel pattern) that significantly reduce undesired flow anomalies that affect detection and measurement of target and non-target components of a sample. In examples, such flow anomalies can include cavitation and bubbles, that contribute to noise during measurement.

Embodiments of the system(s) can include a single channel for sample processing, in order to obtain measurements of target and non-target components of a sample (e.g., nucleic acid, nucleic acid bound to another component, etc.); however, embodiments of the system(s) can include more than a single channel.

Embodiments of the system(s) can include a seal (e.g., polymer seal, gasket) configured to contain a sample within the system during sample processing. The seal can be configured within and/or about one or more bodies (e.g., substrates, such as polycarbonate bodies) defining a microfluidic channel network for sample processing. In particular, geometric features and thicknesses of the seal can ensure proper fluidic sealing while still permitting flow of fluid through the system in a desired manner. Embodiments of the system(s) can additionally or alternatively omit a seal.

Embodiments of the system(s) can include one or more electrodes positioned relative to the microfluidic elements of the system, in order to facilitate driving of charged sample components throughout the system. The electrode(s) can be positioned (e.g., embedded) within microfluidic channels of the network, or can alternatively be positioned outside of the microfluidic channels of the network.

Embodiments of the system(s) can include an interface to a measurement device that is configured to surround the system, receive a signal from the system, and generate outputs related to one or more aspects of the sample(s) being processed.

In embodiments, the system can be configured as a disposable chip for sample processing by an apparatus, where the apparatus includes electronics components with non-transitory computer-readable media having instructions stored thereon, which when executed perform the steps of: resolving, measuring, and/or counting molecules of a sample being processed. Furthermore, the system and apparatus can be configured to process low sample volumes (e.g., less than 10 mL, less than 1 mL, less than 10 uL, less than 1 uL, less than 10 nL, less than 1 nL, etc.) in a manner that reduces burden on an operator (during manual use), with automated startup features configured to improve efficiency of processing samples.

In examples, the apparatus can generate measurements with a bandwidth of 30 kHz, a sampling rate of 125 kHz, and an IRMS noise of ˜20 pA (2M LiCl); however, in alternative embodiments, the apparatus can generate measurements with another suitable bandwidth, sampling rate, and/or IRMS noise under other conditions of use.

In one embodiment, the system can provide functionality for applications in agriculture technology, including detection and/or quantification of crop traits, pathogens, and resistant pathogens for sustainable crop production. In particular, farmers and agricultural land managers globally have increasingly adopted the use of crops with genetic modifications that introduce novel traits, such as resistance to herbicides or pests. To address public concern around food safety, different countries have defined regulations that restrict these technologies and their use in food products, which requires reliable detection and quantitative analytical methods for the implementation of labeling requirements. Such methods are based either on DNA detection (e.g., using polymerase chain reaction (PCR)-based assays, etc.), or protein detection (e.g., using lateral flow strips, using enzyme-linked immunosorbent assays (ELISAs), etc.). Such techniques can be slow and labor intensive, especially if a high degree of accuracy is required.

Embodiments of the invention(s) described herein, however, provide systems and methods for returning highly accurate results (e.g., with maximum error of 5% across the entire dynamic range, compared to 20% error for quantitative PCR methods) using solid-state nanopore systems with novel features.

In one embodiment, the system can provide functionality for applications in diagnostics (e.g., human diagnostics), such as point of care diagnostics for various health conditions.

In one embodiment, the system can provide functionality for applications in research and discovery associated with one or more of: genome mapping, structural variant mapping, epigenetics, and other disciplines of research. Example applications can include analysis of genetic rearrangements (e.g., for diagnostics), interrogation of DNA methylation profiles, analysis of histone modification states of chromosomal fragments, drug development, liquid biopsy performance, and/or other applications.

### BRIEF DESCRIPTION OF DRAWINGS

FIG. 1 depicts an exploded view of a system for sample processing.

FIG. 2 depicts a cross-section view of a chip associated with the system shown in FIG. 1.

FIG. 3A depicts a view of a portion of the system shown in FIG. 1, including microfluidic features that prevent cavitation and bubbling during sample processing.

FIG. 3B depicts a cross-section view of a portion of the system shown in FIG. 3A, which includes microfluidic features that prevent cavitation and bubbling during sample processing.

FIG. 3C depicts a plan view and a cross sectional view portion of the system shown in FIG. 1, including microfluidic features.

FIG. 3D depicts a top view and a cross-sectional view of the portion of the system shown in FIG. 1, including microfluidic features.

FIG. 4A depicts plan and cross-sectional views of a portion of a system (e.g., seal) for sample processing.

FIG. 4B depicts cross-sectional views of the system shown in FIG. 4A.

FIG. 4C depicts isometric views and assembly notes associated with the system shown in FIG. 4A.

FIG. 5A depicts an exploded view of a system for sample processing, including an apparatus that supports and processes signals generated by the system in order to return outputs to a user or other operator.

FIG. 5B depicts interaction between embodiments of components shown in FIGS. 1 and 5A.

The figures depict embodiments of the present invention for purposes of illustration only. One skilled in the art will readily recognize from the following discussion that alternative embodiments of the structures and methods illustrated herein may be employed without departing from the principles of the invention described herein.

### Definitions

The terms “polynucleotide” and “nucleic acid,” used interchangeably herein, refer to a polymeric form of nucleotides of any length, either ribonucleotides or deoxyribonucleotides. Thus, this term includes, but is not limited to, single-, double-, or multi-stranded DNA or RNA, genomic DNA, cDNA, DNA-RNA hybrids, or a polymer comprising purine and pyrimidine bases or other natural, chemically or biochemically modified, non-natural, or derivatized nucleotide bases.

The terms “peptide,” “polypeptide,” and “protein” are used interchangeably herein, and refer to a polymeric form of amino acids of any length, which can include coded and non-coded amino acids, chemically or biochemically modified or derivatized amino acids, and polypeptides having modified peptide backbones.

In some instances, a component (e.g., a nucleic acid component; a protein component; and the like) includes a label moiety. The terms “label”, “detectable label”, or “label moiety” as used herein refer to any moiety that provides for signal detection and may vary widely depending on the particular nature of the assay. Label moieties of interest include both directly detectable labels (direct labels) (e.g., a fluorescent label) and indirectly detectable labels (indirect labels) (e.g., a binding pair member). A fluorescent label can be any fluorescent label (e.g., a fluorescent dye (e.g., fluorescein, Texas red, rhodamine, ALEXAFLUOR® labels, and the like), a fluorescent protein (e.g., green fluorescent protein (GFP), enhanced GFP (EGFP), yellow fluorescent protein (YFP), red fluorescent protein (RFP), cyan fluorescent protein (CFP), cherry, tomato, tangerine, and any fluorescent derivative thereof), etc.). Suitable detectable (directly or indirectly) label moieties may include any moiety that is detectable by spectroscopic, photochemical, biochemical, immunochemical, electrical, optical, chemical, or other means. For example, suitable indirect labels include biotin (a binding pair member), which can be bound by streptavidin (which can itself be directly or indirectly labeled). Labels can also include: a radiolabel (a direct label)(e.g., ³H, ¹²⁵I, ³⁵S, ¹⁴C, or ³²P); an enzyme (an indirect label)(e.g., peroxidase, alkaline phosphatase, galactosidase, luciferase, glucose oxidase, and the like); a fluorescent protein (a direct label)(e.g., green fluorescent protein, red fluorescent protein, yellow fluorescent protein, and any convenient derivatives thereof); a metal label (a direct label); a colorimetric label; a binding pair member; and the like. By “partner of a binding pair” or “binding pair member” is meant one of a first and a second moiety, wherein the first and the second moiety have a specific binding affinity for each other. Suitable binding pairs include, but are not limited to: antigen/antibodies (for example, digoxigenin/anti-digoxigenin, dinitrophenyl (DNP)/anti-DNP, dansyl-X-anti-dansyl, fluorescein/anti-fluorescein, lucifer yellow/anti-lucifer yellow, and rhodamine anti-rhodamine), biotin/avidin (or biotin/streptavidin) and calmodulin binding protein (CBP)/calmodulin. Any binding pair member can be suitable for use as an indirectly detectable label moiety.

Any given component, or combination of components can be unlabeled, or can be detectably labeled with a label moiety. In some cases, when two or more components are labeled, they can be labeled with label moieties that are distinguishable from one another.

Before the present invention is further described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a,” “an,” and “the” include plural referents unless the context clearly dictates otherwise. Thus, for example, reference to “a ribonucleoprotein complex” includes a plurality of such complexes and reference to “the mutant dystrophin gene” includes reference to one or more mutant dystrophin genes and equivalents thereof known to those skilled in the art, and so forth. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination. All combinations of the embodiments pertaining to the invention are specifically embraced by the present invention and are disclosed herein just as if each and every combination was individually and explicitly disclosed. In addition, all sub-combinations of the various embodiments and elements thereof are also specifically embraced by the present invention and are disclosed herein just as if each and every such sub-combination was individually and explicitly disclosed herein.

### DETAILED DESCRIPTION

### Nanopore Devices

In some embodiments, a nanopore device includes at least one nanopore that forms an opening in a structure separating an interior space of the nanopore device into two volumes.

The nanopore devices also includes at least a sensor in electrical communication with the opening and configured to identify objects (for example, by detecting changes in electrical signal parameters indicative of objects) passing through the nanopore. Nanopore devices that may be used for the methods and systems described herein are also disclosed in U.S. application Ser. No. 17/112,846, PCT Publication Nos. WO/2013/012881 and WO/2018/236673, U.S. Application Publication No. 2017/0145481, U.S. Pat. Nos. 9,863,912, and 10,488,394, which are hereby incorporated by reference in their entirety. Amplifiers and circuitry in the nanopore devices that may be used for the methods and systems are also disclosed in U.S. Application Publication No. 2017/0145481, which is hereby incorporated by reference in its entirety.

In some embodiments, the nanopore(s) in the nanopore device(s) are nanoscale or microscale in relation to characteristic feature dimensions. In one aspect, each pore has a size that allows a small or large molecule (e.g., nucleic acid molecule or fragment) or microorganism to pass. In examples, nanopores can have a diameter from 1 nm through 100 nm; however, in variations of the examples, nanopores can have a diameter less than 1 nm or greater than 100 nm. In some embodiments, the diameter of the pores range from about 2 nm to about 50 nm. In some embodiments, the diameter of the pores is about 20 nm. In variations, a nanopore has a depth ranging from 1-10,000 nm; however, in other variations, a nanopore can have a depth less than 1 nm or greater than 10,000 nm. Furthermore, during an experimental run, nanopore dimensions may vary (within a suitable range), as described in further detail below.

In some aspects, each of the pores in the nanopore device independently has a size that allows a small or large molecule or microorganism to pass. In some embodiments, each pore is at least about 1 nm in diameter. Alternatively, each pore is at least about 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 35 nm, 40 nm, 45 nm, 50 nm, 60 nm, 70 nm, 80 nm, 90 nm or 100 nm in diameter.

In some aspects, the pore has a diameter that is between about 1 nm and about 100 nm, or alternatively between about 2 nm and about 80 nm, or between about 3 nm and about 70 nm, or between about 4 nm and about 60 nm, or between about 5 nm and about 50 nm, or between about 10 nm and about 40 nm, or between about 15 nm and about 30 nm.

In some embodiments, a nanopore of a nanopore device has a substantially round shape. “Substantially round”, as used here, refers to a shape that is at least about 80 or 90% in the form of a cylinder. However, in alternative embodiments, a nanopore device can include nanopores that are square, rectangular, triangular, oval, hexangular, or of another morphology.

In some embodiments, the nanopore extends through a membrane. For example, the pore may be a protein channel inserted in a lipid bilayer membrane or it may be engineered by drilling, etching, or otherwise forming the pore through a solid-state substrate such as silicon dioxide, silicon nitride, grapheme, or layers formed of combinations of these or other materials.

In some embodiments, nanopores of a device can be spaced apart at distances ranging from 5-15,000 nm. In some embodiments, the nanopores of a device can be spaced apart at distances ranging from 10 to 1000 nm. However, in other variations, nanopores can be spaced apart less than 5 nm or greater than 15,000 nm. Furthermore, nanopores can be arranged in any position so long as they allow fluid communication between the chambers and have the prescribed size and distance between them. In some embodiments, the first pore and the second pore are about 10 nm to 500 nm apart from each other. In some embodiments, the first pore and the second pore are about 500 nm apart from each other. In one variation, the nanopores are placed so that there is no direct blockage between them. Still, in one aspect, the pores are substantially coaxial.

In some cases, the diameter of the pores ranges from about 2 nm to about 50 nm. In some cases, the diameter of the pore is about 20 nm. In some cases, the diameter of the first and/or second pore ranges from about 2 nm to about 50 nm. In some cases, the diameter of the first and/or second pore ranges from about 2 nm to about 8 nm. In some cases, the diameter of the first and/or second pore ranges from about 10 nm to about 20 nm. In some cases, the diameter of the pore ranges from about 20 nm to about 30 nm. In some cases, the diameter of the first and/or second pore ranges from about 30 nm to about 40 nm. In some cases, the diameter of the first and/or second pore ranges from about 40 nm to about 50 nm. In some cases, the diameter of the first and/or second pore is about 2 nm, about 4 nm, about 6 nm, about 8 nm, about 10 nm, about 12 nm, about 14 nm, about 16 nm, about 18 nm, about 20 nm, about 22 nm, about 24 nm, about 26 nm, about 28 nm, about 30 nm, about 32 nm, about 34 nm, about 36 nm, about 38 nm, about 40 nm, about 42 nm, about 44 nm, about 46 nm, about 48 nm, or about 50 nm. In some cases, the diameter of the first and/or second pore is about 19 nm. In some cases, the first pore and the second pore have the same diameters. In some cases, the diameter of the first and/or second pore is about 21 nm. In some cases, the diameter of the first and/or second pore is about 22 nm. In some cases, the diameter of the first and/or second pore is about 23 nm. In some cases, the diameter of the first and/or second pore is about 24 nm. In some cases, the diameter of the first and/or second pore is about 25 nm. In some cases, the diameter of the first and/or second pore is about 27 nm. In some cases, the diameter of the first and/or second pore is about 29 nm. In some cases, the first pore and the second pore have different diameters. In some cases, the diameter of the pore is about 20 nm.

In some embodiments, the device comprises a geometrically constrained fluidic volume. In some cases, the geometrically constrained fluidic volume is a fluidic channel. In some cases, the shape of the fluidic channel(s) can be circular, square, rectangular, hexagonal, triangular, oval, polygon, V-shape, U-shape, or any other suitable shape. In some cases, the fluidic channels of the nanopore device comprises one or more openings on a side opposite of the first and/or second pores. In some cases, the fluidic channels of the nanopore device comprises two openings on a side opposite of the first and/or second pores.

In some embodiments, the nanopore device has electrodes positioned in the fluidic channels, geometrically constrained volume, or chambers and coupled to one or more power supplies in order to apply voltages across the nanopore(s). In some aspects, the power supply includes a voltage-clamp or a patch-clamp, which can supply a voltage across each pore and measure the current through each pore independently. In this respect, the power supply and the electrode configuration can set the chamber to a common ground for both power supplies. As such each nanopore can have its own respective applied voltage.

In some aspects, a first voltage V1 and a second voltage V2 of different nanopores of a nanopore device are independently adjustable. In one aspect, where multiple nanopores are connected by a chamber, the chamber can be adjusted to be a ground relative to the two voltages. In one aspect, the chamber comprises a medium for providing conductance between each of the pores and the electrode in the chamber. In one aspect, the chamber includes a medium for providing a resistance between each of the nanopores and the electrode in the chamber. Keeping such a resistance sufficiently small relative to the nanopore resistances is useful for decoupling the two voltages and currents across the pores, which is helpful for the independent adjustment of the voltages.

Adjustment of the voltages can be used to control the movement of charged particles with respect to a pore (e.g., through the pore). For instance, when both voltages are set in the same polarity, a properly charged particle can be moved from the first fluidic channel to the chamber and to the second fluidic channel, or the other way around, sequentially. In some aspects, when the two voltages are set to opposite polarity, a charged particle can be moved from either the first fluidic channel or the second fluidic channel to the chamber and kept there.

The adjustment of the voltages in the device can be particularly useful for controlling the movement of a large molecule, such as a charged polymer, that is long enough to cross both pores at the same time. In such an aspect, the direction and the speed of the movement of the molecule can be controlled by the relative magnitude and polarity of the voltages as described below.

In some cases, the first initial voltage ranges from 0 mV to 1000 mV. In some cases, the first initial voltage ranges from 100-200 mV, 200-300 mV, 300-400 mV, 400-500 mV, 500-600 mV, 600-700 mV, 700-800 mV, 800-900 mV, 900-1000 mV, or 1000 or more mV. In some cases, the first initial voltage is 100 mV, 200 mV, 300 mV, 400 mV, 500 mV, 600 mV, 700 mV, 800 mV, 900 mV, or 1000 mV. In some cases, the second initial voltage ranges from 0 mV to 1000 mV. In some cases, the second initial voltage ranges from 100-200 mV, 200-300 mV, 300-400 mV, 400-500 mV, 500-600 mV, 600-700 mV, 700-800 mV, 800-900 mV, 900-1000 mV, or 1000 or more mV. In some cases, the second initial voltage is 100 mV, 200 mV, 300 mV, 400 mV, 500 mV, 600 mV, 700 mV, 800 mV, 900 mV, or 1000 mV.

In some cases, the methods of the present disclosure comprise adjusting the first and/or second voltages to control the movement of the target polynucleotide relative to one or more pores of the nanopore device.

In some aspects, repeated controlled delivery for re-sequencing a polynucleotide, for instance, with respect to enrichment of target material from a sample, further improves the quality of sequencing. Each voltage is alternated as being larger, for controlled delivery in each direction.

The device can contain materials suitable for holding liquid samples, in particular, biological samples, and/or materials suitable for nanofabrication. In one aspect, such materials include dielectric materials such as, but not limited to, silicon, silicon nitride, silicon dioxide, graphene, carbon nanotubes, TiO2, HfO2, Al2O3, or other metallic layers, or any combination of these materials. In some aspects, for example, a single sheet of graphene membrane of about 0.3 nm thick can be used as the pore-bearing membrane.

Nanopore devices that are microfluidic can be made by a variety of means and methods. A focused electron or ion beam can be used to drill pores through the membranes, naturally aligning them. The pores can also be sculpted (shrunk) to smaller sizes by applying a correct beam focusing to each layer. Any single nanopore drilling method can also be used to drill the pair of pores in the two membranes, with consideration to the drill depth possible for a given method and the thickness of the membranes. Predrilling a micro-pore to a prescribed depth and then a nanopore through the remainder of the membranes is also possible to further refine the membrane thickness. In one example, a single beam can be used to form one or more nanopores (e.g., concentric nanopores) in a membrane of the nanopore device. Alternatively, in another example, different beams can be applied to each side of the membranes, in order to generate aligned or non-aligned nanopores.

More specifically, the nanopore-bearing membranes can be made with transmission electron microscopy (TEM) grids with a 5-100 nm thick silicon, silicon nitride, or silicon dioxide windows. Spacers can be used to separate the membranes, using an insulator, such as SU-8, photoresist, PECVD oxide, ALD oxide, ALD alumina, or an evaporated metal material, such as Ag, Au, or Pt, and occupying a small volume within the otherwise aqueous portion of a middle chamber (e.g. chamber).

By virtue of the voltages present at the pore(s) of the device, charged molecules can be moved through the pore. Speed and direction of the movement can be controlled by the magnitude and polarity of the voltages.

In some aspects, a nanopore device further includes means to move a polymer across the pore and/or means to identify objects that pass through the pore. In some embodiments, the polymer is a polynucleotide or a polypeptide. In some aspects, the polymer is a polynucleotide. Non-limiting examples of polynucleotides include double-stranded DNA, single-stranded DNA, double-stranded RNA, single-stranded RNA, and DNA-RNA hybrids.

In some aspects, the nanopore device can be used to identify one or more features of a polymer. In some embodiments, the one or more features is one feature, two features, three features, four features, or five features. In some embodiments, the one or more features is two or more features, three or more features, four or more features, five or more features, six or more features, seven or more features, eight or more features, nine or more features, or ten or more features. In some embodiments, the one or more features ranges from 1-5 features, 5-10 features, 10-15 features, 15-20 features, 20-25 features, 25-30 features, 30-35 features, 35-40 features, 40-45 features, or 45-50 features. In some embodiments, the one or more features ranges from 50 features to 100 features, 100 features to 1,000 features, 1,000 features to 10,000 features, 10,000 features to 100,000, 100,000 features to 200,000 features. In some embodiments, the one or more features is 50 features or more, 100 features or more, 1,000 features or more, 10,000 features or more, 100,000 features or more, or 200,000 features or more.

Aspects of the present disclosure include one or more features, wherein each feature is about from one another by about 100 base pairs, 300 base pairs, 500 base pairs, 1 kilo-base pair, 5 kilo base-pair, 10 kilo base pair, 20 kilo-base pair, or a combination thereof. In some embodiments, each features is spaced about from one another by about 25 base pairs or more, about 50 base pairs or more, about 100 base pairs or more, about 300 base pairs or more, about 500 base pairs or more, about 1 kilo-base pair or more, about 5 kilo base-pairs or more, about 10 kilo base pairs or more, about 20 kilo-base pairs or more, or a combination thereof. In some embodiments, each features is spaced about from one another by about 25 base pairs or less, about 50 base pairs or less, about 100 base pairs or less, about 300 base pairs or less, about 500 base pairs or less, about 1 kilo-base pair or less, about 5 kilo base-pairs or less, about 10 kilo base pairs or less, about 20 kilo-base pairs or less, or a combination thereof.

In some aspects, the nanopore device can be used to identify a first set of features, a second set of features, a third set of features, a fourth set of features, a fifth set of features, a sixth set of features, a seventh set of features, an eighth set of features, a ninth set of features, and/or a tenth set of features. In some cases, each set of features comprises one or more features ranges from 1-5 features, 5-10 features, 10-15 features, 15-20 features, 20-25 features, 25-30 features, 30-35 features, 35-40 features, 40-45 features, or 45-50 features. In some embodiments, the first set of features overlaps with the second set of features. In some embodiments, the third set of features overlaps with the fourth set of features. In some embodiments, the first set of features partially overlaps with the second set of features. In some embodiments, the third set of features partially overlaps with the fourth set of features. In some embodiments, the first set of features are the same as the second set of features. In some embodiments, the third set of features are the same as the fourth set of features. In some embodiments, the first set of features are different from the second set of features. In some embodiments, the third set of features are different from the fourth set of features.

In some embodiments, the sets of features (e.g. first set, second set, third set, fourth set, fifth set, sixth set, seventh set, eighth set, ninth set, and/or tenth set) are associated with a first cycle, a second cycle, a third cycle, a fourth cycle, a fifth cycle, a sixth cycle, a seventh cycle, an eighth cycle, a ninth cycle, and/or a tenth cycle, respectively. In some cases, a first cycle comprises one or more scans performed by a processor to detect the first set of features. In some cases, the first cycle comprises two or more scans, three or more scans, four or more scans, five or more scans, six or more scans, seven or more scans, eight or more scans, nine or more scans, or ten or more scans. In some cases, the first cycle comprises two or more scans, four or more scans, six or more scans, eight or more scans, ten or more scans, twelve or more scans, fourteen or more scans, sixteen or more scans, eighteen or more scans, or twenty or more scans. In some cases, the first cycle comprises five or more scans, ten or more scans, fifteen or more scans, twenty or more scans, twenty-five or more scans, thirty or more scans, thirty-five or more scans, forty or more scans, forty-five or more scans, or fifty or more scans.

In some cases, the second cycle comprises one or more scans performed by a processor to detect the third set of features. In some cases, the second cycle comprises two or more scans, three or more scans, four or more scans, five or more scans, six or more scans, seven or more scans, eight or more scans, nine or more scans, or ten or more scans. In some cases, the second cycle comprises two or more scans, four or more scans, six or more scans, eight or more scans, ten or more scans, twelve or more scans, fourteen or more scans, sixteen or more scans, eighteen or more scans, or twenty or more scans. In some cases, the second cycle comprises five or more scans, ten or more scans, fifteen or more scans, twenty or more scans, twenty-five or more scans, thirty or more scans, thirty-five or more scans, forty or more scans, forty-five or more scans, or fifty or more scans. In some cases, the first cycle and the second cycle, together, comprise 50 or more scans, 100 or more scans, 150 or more scans, 200 or more scans, 250 or more scans, 300 or more scans, 350 or more scans, 400 or more scans, or 500 or more scans. In some embodiments, the first cycle, second cycle, third cycle, fourth cycle, and fifth cycle, together, comprise 50 or more scans, 100 or more scans, 150 or more scans, 200 or more scans, 250 or more scans, 300 or more scans, 350 or more scans, 400 or more scans, or 500 or more scans.

Aspects of the present disclosure include a processor and a computer-readable medium, comprising instructions that cause the processor to repeat the determining the presence of the target polynucleotide in both pores, scanning for one or more features, and changing the voltage to control movement of the polynucleotide (e.g. in either direction) for a third cycle, a fourth cycle, and a fifth cycle; or when the polynucleotide exits the device, or otherwise enters a chamber of the device for retrieval and/or subsequent downstream processing.

In some aspects, the nanopore device can be used to identify one or more features of a polymer. In some embodiments, the polymer is a polynucleotide. In some embodiments, the one or more features of the polynucleotide comprises one or more features associated with the polynucleotide. Non-limiting examples of one or more features associated with the polynucleotide, include, but are not limited to, transcription factors, nucleosomes, or modifications to the features, including modification to histone tails. In some embodiments, one or more features in the polynucleotide comprises one or more sequence or structural variations.

In some embodiments, the one or more features of the polynucleotide comprises one or more payload molecules bound to the polynucleotide. In some embodiments, the one or more features of the polynucleotide comprises one or more payload molecules hybridized to the polynucleotide. In some embodiments, the one or more features of the polynucleotide comprises one of more payload molecules incorporated into the genome of the polynucleotide. In some embodiments, the one or more features of the polynucleotide comprises a molecular motif on a polynucleotide sequence of the target polynucleotide. In some embodiments, the one or more features comprises the position of: one or more CpG's; or one or more methylation cites and CpG's, on the polynucleotide sequence of the target polynucleotide. In some embodiments, the one or more features comprises the position of one or more histones on the target polynucleotide. In some embodiments, the one or more features comprises a molecule selected from the group consisting of: a nucleic acid, a TALEN, a CRISPR, a peptide nucleic acid, and a chemical compound. In some embodiments, the one or more features comprises a DNA-binding protein, a polypeptide, an anti-DNA antibody, a streptavidin, a transcription factor, a histone, a peptide nucleic acid (PNA), a DNA-hairpin, a DNA molecule, an aptamer, or a combination thereof.

Non-limiting examples of payload molecules bound to the polynucleotide can be found in can be found in U.S. Patent Publication No. 2018/0023115, which is hereby incorporated by reference in its entirety. For example, a payload molecule can include a dendrimer, double stranded DNA, single stranded DNA, a DNA aptamer, a fluorophore, a protein, a polypeptide, a nanorod, a nanotube, fullerene, a PEG molecule, a liposome, or a cholesterol-DNA hybrid. In some embodiments, the polynucleotide and the payload are connected directly or indirectly via a covalent bond, a hydrogen bond, an ionic bond, a van der Waals force, a hydrophobic interaction, a cation-pi interaction, a planar stacking interaction, or a metallic bond. The payload adds size to the target polynucleotide or amplicon, and facilitates detection, with the amplicon bound to the payload having a markedly different current signature when passing through the nanopore than background molecules. In some embodiments, the payload molecule comprises an azide chemical handle for attachment to a primer. In some embodiments, the primer is bound to a biotin molecule. In some embodiments, the payload molecule can bind to another molecule to affect the bulkiness of the molecule, thereby enhancing the sensitivity of detection of the amplicon in a nanopore. In some embodiments, the primer is bound to or comprises a binding site for binding to a biotin molecule. In some embodiments, the biotin is further bound by streptavidin to increase the size of the payload molecule for enhanced detection in a nanopore over background molecules. The added bulk can produce a more distinct signature difference between amplicon comprising a target sequence and background molecules.

In this embodiment, attachment of a payload to a primer or amplicon can be achieved in a variety of ways. For example, the primer may be a dibenzocyclooctyne (DBCO) modified primer, effectively labeling all amplicons with a DBCO chemical group to be used for conjugation purposes via copper-free “click” chemistry to an azide-tagged amplicon or primer.

In some aspects, the primer comprises a chemical modification that causes or facilitates recognition and binding of a payload molecule. For example, methylated DNA sequences can be recognized by transcription factors, DNA methyltransferases or methylation repair enzymes. In other embodiments, biotin may be incorporated into, and recognized by, avidin family members. In such embodiments, biotin forms the fusion binding domain and avidin or an avidin family member is the polymer scaffold-binding domain on the fusion. Due to their binding complementarity, payload molecule binding domains on a primer/amplicon and primer binding domains on a payload molecule may be reversed so that the payload binding domain becomes the primer binding domain, and vice versa.

Molecules, in particular, proteins, that are capable of specifically recognizing nucleotide binding motifs are known in the art. For instance, protein domains such as helix-turn-helix, a zinc finger, a leucine zipper, a winged helix, a winged helix turn helix, a helix-loop-helix and an HMG-box, are known to be able to bind to nucleotide sequences. Any of these molecules may act as a payload molecule binding to the amplicon or primer. In some aspects, the payload binding domains can be locked nucleic acids (LNAs), bridged nucleic acids (BNA), Protein Nucleic Acids of all types (e.g. bisPNAs, gamma-PNAs), transcription activator-like effector nucleases (TALENs), clustered regularly interspaced short palindromic repeats (CRISPRs), or aptamers (e.g., DNA, RNA, protein, or combinations thereof). In some aspects, the payload binding domains are one or more of DNA binding proteins (e.g., zinc finger proteins), antibody fragments (Fab), chemically synthesized binders (e.g., PNA, LNA, TALENS, or CRISPR), or a chemical modification (i.e., reactive moieties) in the synthetic polymer scaffold (e.g., thiolate, biotin, amines, carboxylates).

In some embodiments, the one or more features comprises one or more features in the polynucleotide. In some embodiments, the one or more features in the polynucleotide comprises one or more modifications to the polynucleotide. In some embodiments, the one or more modifications comprises DNA methylation (e.g. 5mC, 5hmC, e.g., at CpG dinucleotides, 5 mA, and the like). In some embodiments, the one or more features in the polynucleotide comprise sequence variations, mutations, or larger structural variations. In some embodiments, the one or more features in the polynucleotide comprises rearrangements, deletions, insertions, and/or translocations to the polynucleotide sequence.

In some embodiments, the one or more features comprises one or more features on the polynucleotide. In some embodiments, the one or more features on the polynucleotide comprises a modification to the polynucleotide. In some embodiments, the modification comprises a molecule bound to a monomer. In some embodiments, the one or more features on the polynucleotide comprises one or more molecules bound to the polynucleotide. In some embodiments, the modification comprises the binding of a molecule to the polynucleotide. For instance, for a DNA molecule, the bound molecule can be a DNA-binding protein, such as RecA, NF-κB and p53. In some embodiments, the modification is a particle that binds to a particular monomer or fragment. For instance, quantum dots or fluorescent labels bound to a particular DNA site for the purpose of genotyping or DNA mapping can be detected by the device.

In some embodiments, the polynucleotide sequence comprises one or more nick sites. As a non-limiting example, a nicking restriction endonuclease introduces a nick at the recognition sequence for bar coding. This sequence appears many times in a genome. A single azide azide N3 labeled nucleotide is introduced at the nick site. The reaction is filtered to remove unincorporated nucleotide. A DNA molecule labeled with a DCBO either 5′, 3′, or body labeled is added to the reaction. The DNA molecule is covalently linked at the nick site via copperless click chemistry. 1000-10000 fold excess DNA molecule can be used. In another non-limiting example, a Cas9 D10A nickase can be used for site-specific labeling. Cas9-D10A is target to a specific site and a single strand nick is introduced. Cas9 D10A is removed. A single azide N3 nucleotide is introduced at the nick site by nick translation. The reaction is filtered to remove unincorporated nucleotide. A DNA molecule labeled with a DCBO either 5′, 3′, or body labeled is added to the reaction. The DNA molecule is covalently linked at the nick site via copperless click chemistry. 1000-10000 fold excess DNA molecule can be used.

In one embodiment, a nanopore device includes a plurality of chambers, each chamber in communication with an adjacent chamber through at least one pore.

In some embodiments, a nanopore device can be a multi-pore device having more than one pore. In some embodiments, a nanopore device can include two nanopores, where a first nanopore is positioned relative to a second nanopore in a manner in order to allow at least a portion of a target polynucleotide to move out of the first nanopore and into the second nanopore. In some embodiments, the nanopore device includes one or more sensors at each nanopore, where a respective sensor is capable of identifying a target polynucleotide during the movement across at least one of the nanopores. In some embodiments, the identification entails identifying individual components of the target polynucleotide. In some embodiments, the identification entails identifying payload molecules bound to the target polynucleotide. When a single sensor is employed, the single sensor may include two electrodes placed at both ends of a pore to measure an ionic current across the pore. In another embodiment, the single sensor comprises a component other than electrodes.

In some aspects, the device further includes means to move a target polynucleotide from one chamber to another. In one aspect, the movement results in loading the target polynucleotide (e.g., the amplification product or amplicon comprising the target sequence) across both the first pore and the second pore at the same time. In another aspect, the means further enables the movement of the target polynucleotide, through the pore(s), in the same direction.

While some variations of nanopore devices are described above, the nanopore device(s) can be configured as described in U.S. Application Publication. No. 2013-0233709, U.S. Pat. No. 9,863,912, and PCT Application Publication No. WO2018/236673, which are hereby incorporated by reference in their entirety.

### Solid-State Nanopore Measurement System

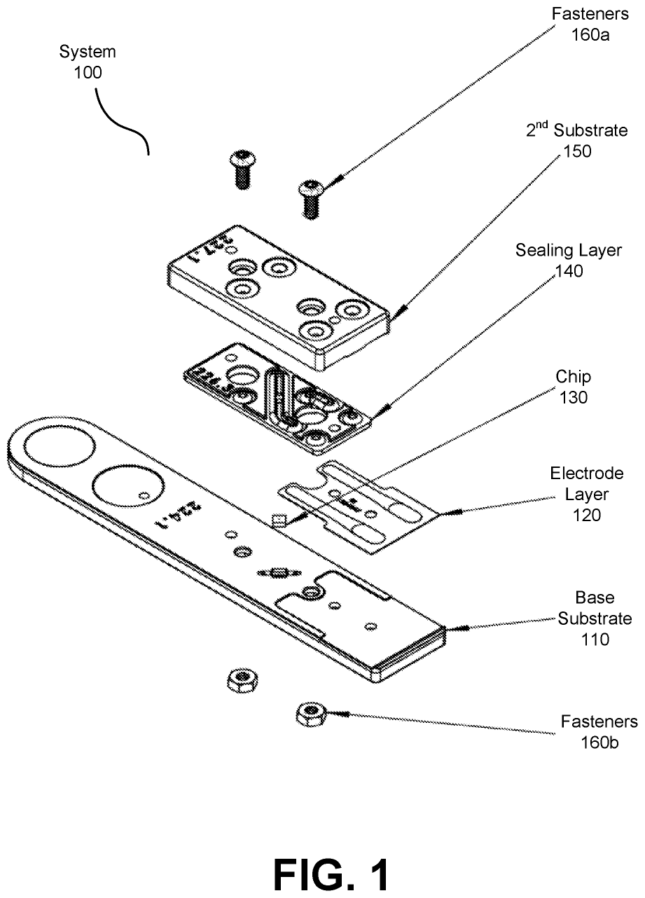

FIG. 1 depicts an exploded view of a system 100 for sample processing. The system 100 includes a test strip 105, which includes functionality for enabling counting and detection of sizes of single molecules (e.g., DNA, RNA, polymers, proteins, etc.); digital output for highly quantitative analysis; conserving samples due to ability to process small sample volumes; returning of rapid results; automated startup features; and other functions.

In applications of use, the system 100 can be used for molecular quantification, sizing, and characterization of DNA molecules. In examples, the system 100 can be used to process 80 base pair to over 100 kilobase pair DNA molecules, with next generation sequencing (NGS) preparation, quality control, and multiplex amplicon detection. Additionally or alternatively, the system 100 can be used for molecular quantification, sizing, and characterization of RNA molecules. In examples, the system 100 can be used for virus detection by multiplex RT-PCR discrimination of RNA from RNA-DNA hybrids, at the single molecule level. Additionally or alternatively, the system 100 can be used for molecular quantification, sizing, and characterization of other polymers. For instance, the system can be used for detection and characterization of actin polymerization (e.g., biological, non-biological). However, the system 100 can be used for molecular quantification, sizing, and characterization of other molecules, of other size ranges, for other suitable applications.

In other applications of use, the system 100 can be used for characterization of macromolecular interactions between DNAs and proteins, RNAs and proteins, proteins and other proteins, and another suitable macromolecular interactions. In examples, the system 100 can be used for characterization of DNA-protein interactions (e.g., of transcription factors), RNA-protein interactions (e.g., splicing machinery), and protein-protein interactions (e.g., antibody-antigen interactions). However, the system 100 can be used for characterization and detection of molecules in other applications of use.

In embodiments, the system 100 includes features that improve efficiency in changing of samples (e.g., features which make sample loading by fluid delivery and/or aspiration elements, such as a pipette). In variations, features can include chamfers at each of the openings of the system 100 (e.g., openings of the test strip portions), which allows for ease of insertion by fluid delivery and/or aspiration elements. In examples, constrictions on the openings can include morphologies that cause the walls near the tip of pipette tip (e.g., a 200 uL pipette tip) to bind with the thru-hole in the strip top (e.g., second substrate 150 described below) to create a seal. System morphologies thus keeps bubbles from being introduced during sample loading, thereby improving sample processing. Additionally or alternatively, in examples, the openings can be surrounded by circular depressions, where the depressions discourage buffer from flowing away from the strip opening during filling. Any fluid thus remains over the opening so that it can be wicked away or otherwise removed (e.g., with a wipe or other porous material).

The embodiment of the system 100 shown in FIG. 1 includes: a base substrate 110; an electrode layer 120 configured to route one or more electrodes for applying voltages (as described above); a chip 130 coupled to the electrode layer 120 and configured to mate with a recessed portion of the base substrate 110; a sealing layer 140 positioned adjacent to the electrode layer 120; a second substrate 150 positioned adjacent to the sealing layer 140; and a set of fasteners 160a, 160b coupling the second substrate 150, the sealing layer 140, the electrode layer 120, the chip 130, and the base substrate 110 together as an assembly. The system 100 provides one or more fluidic channels, defined by one or more of the base substrate 110, the electrode layer 120, the chip 130, the sealing layer 140, and the second substrate 150, in a pattern that minimizes the occurrence of cavitation and bubbles during sample processing (e.g., with passing of one or more molecules through the fluidic channels). As such, the system 100 is configured to prevent or otherwise mitigate effects of noise during measurement/detection of molecules of a sample.

In one variation, the system 100 includes: a base substrate 110; an electrode layer 120 configured to route one or more electrodes for voltage application; a chip 130 retained within a cavity of the base substrate and in electrical communication with the electrode layer 120; a sealing layer 140, the electrode layer 120 positioned between the sealing layer 140 and the base substrate 110; a second substrate 150, the sealing layer 140 positioned between the second substrate 150 and at least a portion of the electrode layer 120 and the base substrate 110; and a set of fasteners 160a, 160b compressing the sealing layer 140, the electrode layer 120, and the chip 130 between the second substrate 150 and the base substrate 110.

The base substrate 110 and second substrate 150 function to provide substrates between other elements of the system 100 are positioned and retained in position, in order to provide reliable processing of samples. In composition, the base substrate 110 and the second substrate 150 can be composed of a polymer (e.g., polycarbonate) or other suitable material that has desired mechanical, optical, physical, and/or thermal properties associated with various applications of use. In a specific example, the base substrate 110 and the second substrate 150 are composed of clear polycarbonate, in order to provide suitable rigidity and optical interrogation of contents of the system 100 during sample processing.

The electrode layer 120 is configured to route one or more electrodes for applying voltages (as described above). The electrode channel 120 can include one or more sets of electrodes for application of driving and/or sensing voltages, as described in relation to various operation modes above. In variations, the electrodes can include conductive materials routed through or patterned (e.g., printed) onto the electrode layer 120 in another suitable manner. For instance, in one example, the electrodes include screen printed silver/silver chloride ink printed onto polyethylene terephthalate (PET) of the electrode layer 120, with an anti-abrasive carbon coating at connecting ends of the electrodes. However, variations of the electrodes can be configured/composed in another suitable manner.

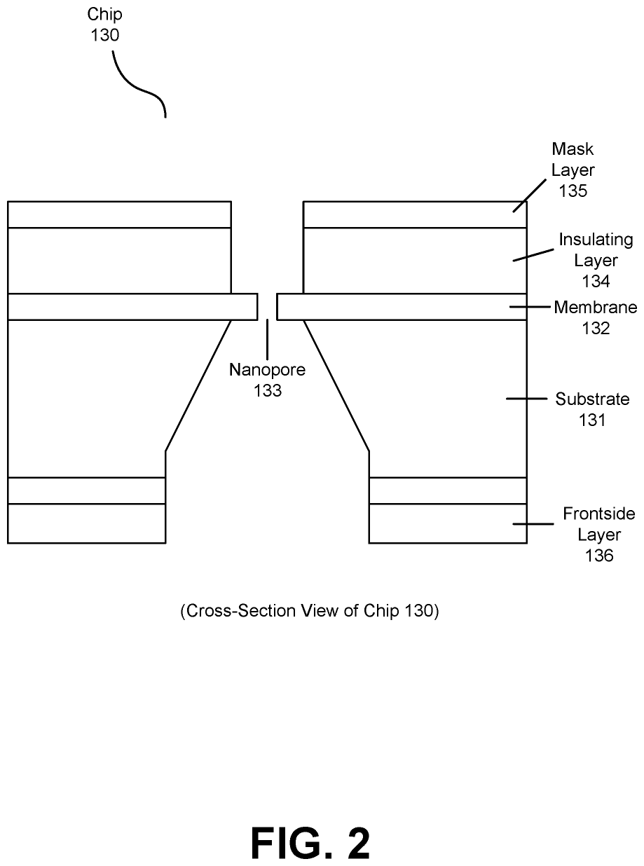

The system 100 is configured to support a chip 130, an embodiment of which is shown in FIG. 2. The chip 130 shown in FIG. 2 includes a substrate 131 to which other layers of the chip 130 are coupled to form a nanopore between two chambers of the chip 130. The substrate 131 can be composed of silicon or another suitable material, as described above. Furthermore, the substrate 131 can have a thickness from 200-1000 um or another suitable thickness. In an example, the substrate 131 is composed of silicon and has a thickness of 750 um; however, variations of the example of the substrate 131 can be configured in another suitable manner.

The chip 130 shown in FIG. 2 also includes a membrane 132 coupled to the substrate 131, through which nanopore 133 is formed (e.g., by electron beam lithography). The membrane 133 can be composed of silicon nitride or another suitable material, as described above. Furthermore, the membrane 132 can have a thickness from 20-100 um or another suitable thickness. The nanopore 133 can have a diameter from 15-50 nm, or a diameter of other suitable dimensions. In an example, the membrane 132 is composed of silicon nitride and has a thickness of 30 um, and the nanopore has a diameter from 25-35 nm; however, variations of the example of the membrane 132 can be configured in another suitable manner.

The chip 130 shown in FIG. 2 also includes an insulating layer 134 coupled to the membrane 132, where the insulating layer functions to reduce noise associated with measurements of molecules passing through the nanopore 133. The insulating layer 134 can be composed of silicon dioxide or another suitable material, as described above. Furthermore, the insulating layer 134 can have a thickness from 0.5 to 5 um or another suitable thickness. In an example, the insulating layer 134 is composed of silicon dioxide and has a thickness of 1 um; however, variations of the example of the insulating layer 134 can be configured in another suitable manner.

The chip 130 shown in FIG. 2 also includes a mask layer 135, which functions to enable formation of other features of the chip 130. The mask layer 135 can be composed of silicon nitride or another suitable material, as described above. Furthermore, the mask layer 135 can have a thickness from 200-800 um or another suitable thickness. In an example, the mask layer 135 is composed of silicon nitride and has a thickness of 400 um; however, variations of the example of the mask layer 135 can be configured in another suitable manner.

The chip 130 shown in FIG. 2 also includes a frontside layer 136, which functions to enable formation of other features of the chip 130. The frontside layer 136 can be composed of silicon nitride or another suitable material, as described above. Furthermore, the frontside layer 136 can have a thickness from 200-800 um or another suitable thickness. In an example, the frontside layer 136 is composed of silicon nitride and has a thickness of 430 um; however, variations of the example of the frontside layer 136 can be configured in another suitable manner.

In a specific example, the chip 130 has a footprint of 3 mm×3 mm; however, variations of the chip 130 can have other suitable dimensions.

Manufacturing of an example of the chip 130 shown in FIG. 2 is described as follows: First, 30 nm of low-stress low-pressure CVD (LPCVD) SiN thin film (<200 MPa, tensile) is deposited on a 750 um Si substrate (e.g., as substrate 131), to form a membrane 132. The nanopores (e.g., as in nanopore 133) are formed in the membrane 132 by first patterning with polymethyl methacrylate and then exposing the 30 nm nanopore pattern using electron beam lithography (EBL), followed by reactive ion etching of the nanopore 133. After the etch the final diameter falls within 25-35 nm. To reduce noise, an insulating layer 134, comprising a 1 um SiO2 layer, is deposited on the front side of the wafer using a plasma-enhanced CVD (PECVD) process followed by a 1000C anneal for one hour. An additional 400 nm SiN etch mask layer 135 was deposited via LPCVD on the substrate 131 following the anneal. The etch pit was opened from the backside by photolithography followed by reactive ion etching of the SiN etch mask layer 135. A second photolithography step was performed on the front side of the wafer to define the SiO2 micro-well pattern. Subsequently, reactive ion etching (ME Oxford PlasmaPro 80) was used to partially open the SiN mask and SiO2 layer with target etch depth of 0.8 um. The membrane 132 was then fully released by removing the remaining oxide and Si material from both sides of the wafer using a KOH wet etch. First, while protecting the frontside of the wafer, a KOH wet etch removed the Si substrate from the etch-pit side. Second, while protecting the backside, another KOH wet etch removed the remaining oxide material from the frontside, fully releasing the membrane 132 and nanopore 133.

The sealing layer 140 is positioned adjacent to the electrode layer 120, and functions to seal the fluidic channels of the system 100. In combination with the set of fasteners 160a, 160b described further below, the sealing layer 140 provides a mechanism for prevention of sample leakage (e.g., liquid leakage, gas leakage) of sample material passing through the fluidic channels/nanopores of the system 100. Thus, the sealing layer 140 provides a system where electrical conductivity between the channels can only occur through the nanopore. In variations, the fluidic channels can have a capacity from 2 to 20 microliters of sample. In a specific example, each channel has a volumetric capacity of 8 microliters. However, variations of the example can have other suitable volumetric capacities. The sealing layer can be composed of an elastomer, or another suitable material configured to provide sealing functions. Additionally or alternatively, the sealing layer 140 can include features (e.g., O-rings, gaskets, adhesives, films, hydrophobic materials, etc.) configured to provide sealing functions in another suitable manner. In a specific example, the sealing layer 140 is composed of a thermoplastic elastomer (e.g., Santoprene™); however, variations of the specific example can include another suitable material composition of the sealing layer 140.

The set of fasteners 160a, 160b functions to couple the second substrate 150, the sealing layer 140, the electrode channel 120, the chip 130, and the base substrate 110 together as an assembly. In combination with the sealing layer 140, the set of fasteners 160a, 160b function to retain positions of individual elements of the assembly relative to each other, and to provide sealing of channels of the system. In examples, the set of fasteners 160a, 160b include screws and nuts; however, variations of the set of fasteners 160a, 160b can alternatively include other suitable fasteners/fastening mechanisms.

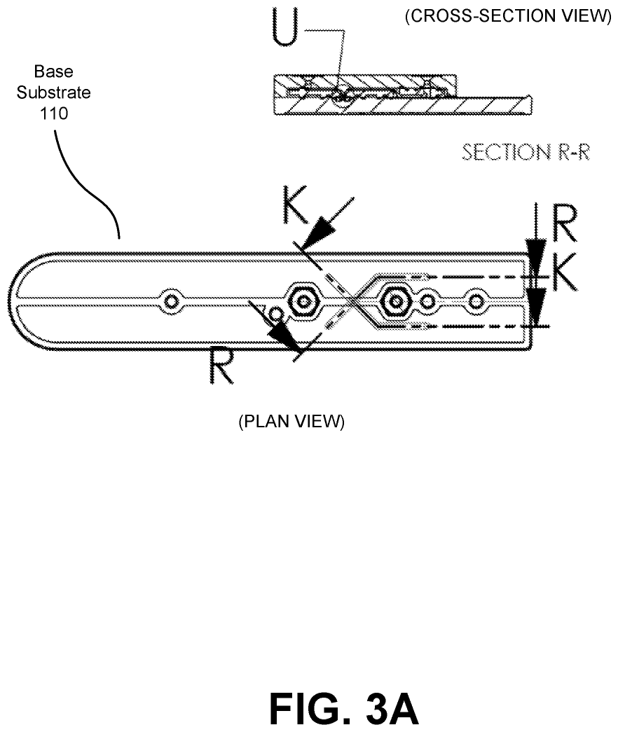

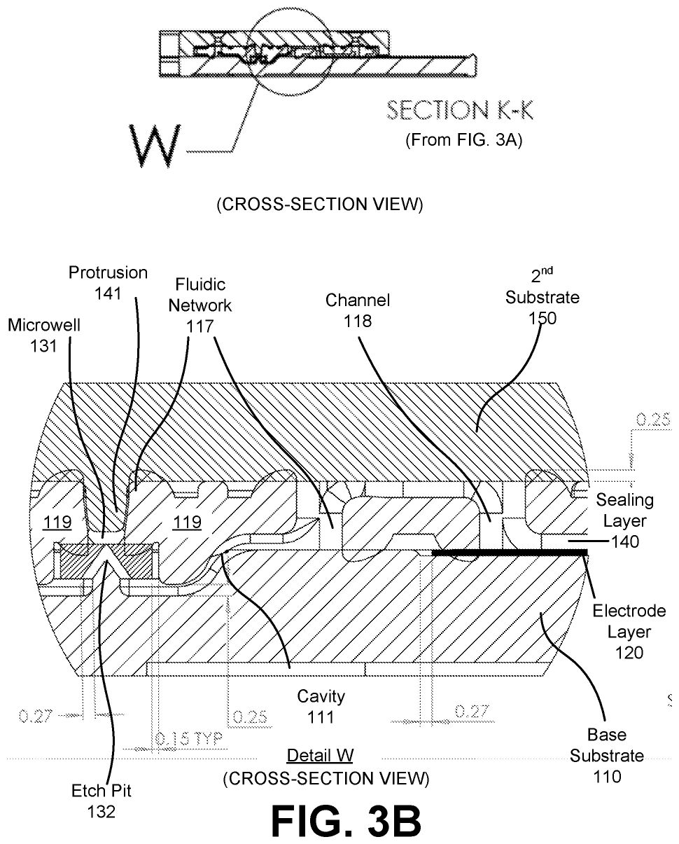

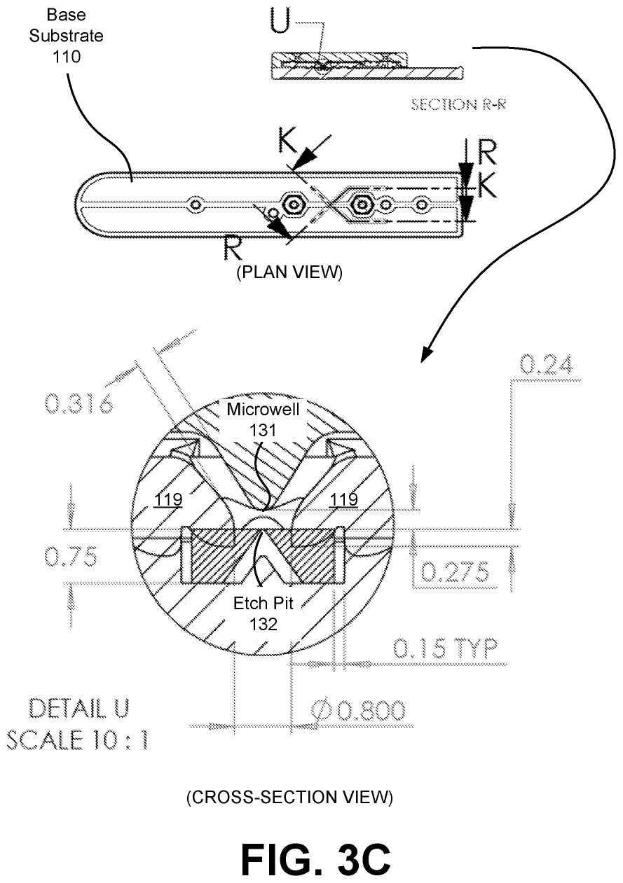

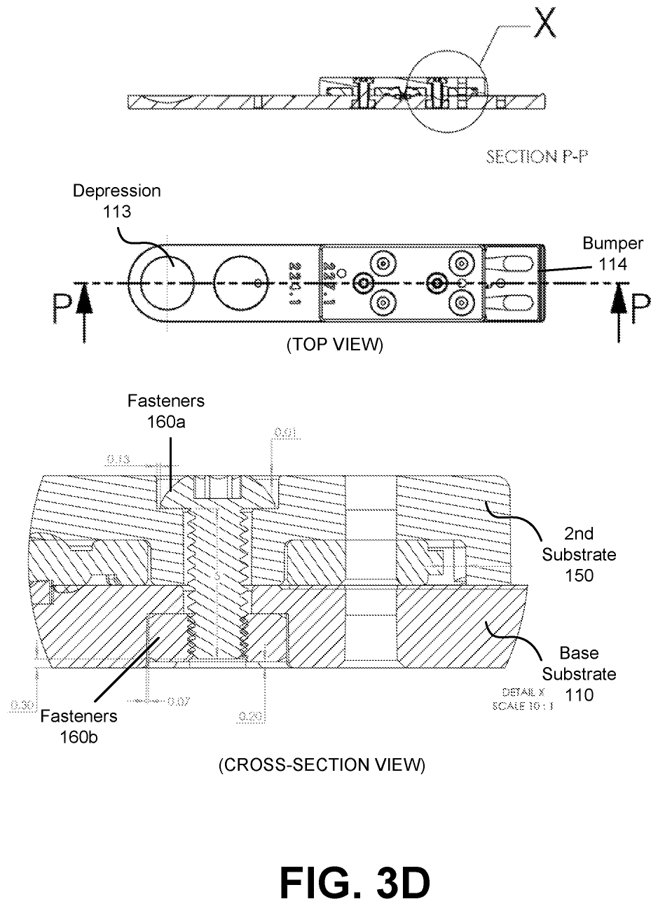

FIG. 3A depicts a bottom view of a portion (i.e., base substrate 110) of the system shown in FIG. 1, where sections K-K, R-R, and feature U are shown in FIGS. 3B and 3C, respectively. FIG. 3B depicts cross-section view K-K, with feature W, which includes microfluidic features that prevent cavitation and bubbling during sample processing. The embodiment shown in FIGS. 3A-3C includes a fluidic network with uniform channel geometries both leading up to and away from the chip 130, in order to promote proper flow without bubble formation. Furthermore, the embodiment shown in FIGS. 3A-3C include morphologies that form a uniform, fluid-tight seal along channel edges of the fluidic network, where the seal prevents fluid escape from the fluidic network and prevents air ingress into the channels of the fluidic network during flushing of the system 100. As such, features of the components shown in FIGS. 3A-3C are configured to prevent bubble formation and to incentivize nanopore wetting during use of the system 100.

In particular, the channel cross section configurations taken transverse to a flow direction through the channel include non-uniform cross sections including curved boundaries and flat boundaries, with suitable geometries for preventing cavitation and bubbling during flow of a sample containing molecules or other polymers, through the system 100. In more detail, the channel pathways of the fluidic network 117 include morphologies configured to avoid breaks and provide continuity in the sealing interfaces between the sealing layer 140 and the second substrate/base substrate/electrode layer. One such feature is depicted in FIG. 3B, where the fluidic network 117 includes a channel 118, that crosses over boundaries between edges of the electrode layer 130 and the base substrate 110.

Furthermore, the embodiment of the system shown in FIGS. 3A-3C includes flow redirectors 119 around the chip 130, both at a microwell 131 side and an etch pit 132 side of the chip 130, which reduce the dead space created by the seating and sealing surfaces surrounding the chip 130 and allow fluid to more easily flow bubble-free toward and away from the microwell. Alternative variations without such flow features can cause flow issues (restricted flow) and/or poor nanopore startup (i.e. bubble formation).

The embodiment shown in FIGS. 3A-3C also includes features configured to provide long-term, reliable sealing. For instant, the sealing layer 140 is configured to seal firmly against the nanopore side of the chip 130 for long periods of time while also reducing the area of exposed surface at the nanopore to running buffer. Exposure of this face to the CIS side electrolyte buffer is associated with an increase in both measured IRMS and capacitance. The seal geometry in FIG. 3B shows a protrusion 141 toward the nanopore side of the chip 130, configured to provide proper sealing.

FIG. 3C depicts a plan view and a cross sectional view portion of the system shown in FIG. 1, including microfluidic features configured to promote proper sample flow in a manner that prevents cavitation and bubbling. In particular, detail U shown in FIG. 3C depicts a fluidic feature having a tapered cross section that allows proper sample flow with disruption of bubble formation, in relation to sample delivery through the system 100. As shown in FIGS. 3B and 3C, the base substrate 110 is configured to retain the chip 130 within a cavity 111 during assembly to reduce the likelihood of breaking or losing the chip 130. This structure also enables interfacing with a pick-and-place system for automated manufacturing.

FIG. 3D depicts cross-sectional and plan views of a base substrate 110 of the system shown in FIG. 1, where the configuration of the set of fasteners 160a is shown in relation to assembly of the system and sealing of fluidic channels. The embodiment shown in FIG. 3D also includes features configured to promote ease of assembly of the system 100. For instance, FIGS. 1 and 3D depict an embodiment with mechanical closures, such as fasteners 160a/160b shown in FIG. 1 (e.g., instead of an adhesive closure, instead of laser welding or another bonding method, etc.). In the example shown in FIG. 3D, two sets of M2 nuts and screws are tightened down to retain positions of components of the system 100, using a calibrated torque limiting screw-driver. The base substrate 110 is designed to capture the nut and the second substrate 150 is designed with a hard-stop in case the torque limiting screw-driver fails during assembly.

The embodiment shown in FIG. 3D also includes alignment features. For instance, alignment pin hole features in the second substrate 150, base substrate 110, sealing layer 140, and electrode layer 120 allow each piece of the system to interface with an assembly jig that aligns each piece in the proper orientation. One of these pin holes is offset from the center-line of the test strip to reduce assembly error.

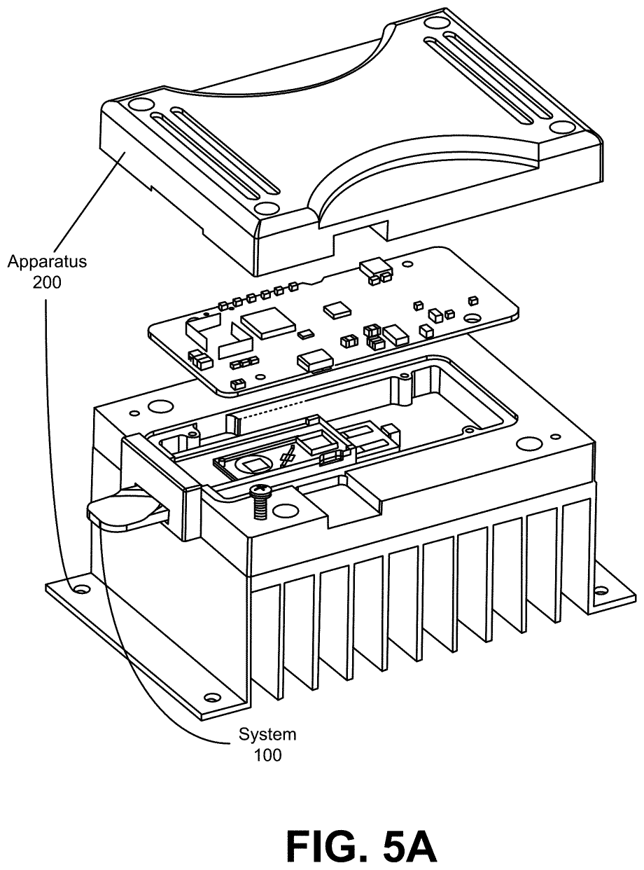

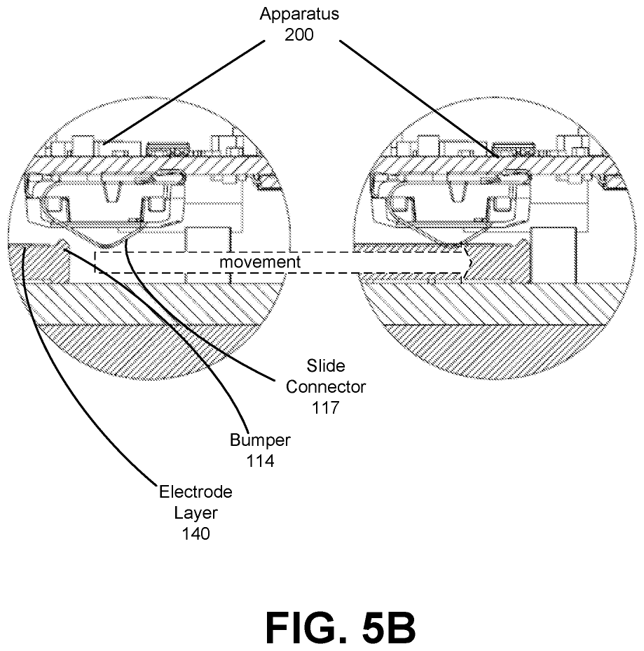

The embodiment shown in FIG. 3D also includes features configured to promote ease of use by a user or other operator of the system 100. In more detail, the system 100 includes one or more depressions 113 in the handle of the base substrate 110 for ergonomic comfort. The system 100 also includes a bumper 114 at an edge of the base substrate 110 that is designed to interface with connectors in an apparatus 200 (shown in FIGS. 5A and 5B) receiving the system 100. The bumper 114 is configured to lift complementary slide connectors 117 in the apparatus 200 and set them down on top of the electrode layer 120, thereby preventing the electrode layer 120 from flipping up during insertion of the system 100 into the apparatus 200.

Variations of the embodiments shown in FIGS. 3A-3C can alternatively be constructed using other manufacturing processes. For instance, one variation can be fabricated by overmolding the chip 130 into a base substrate 110 and assembling the parts (e.g., with ultrasonic welding, heat bonding or other methods). Such variations can omit an elastomer seal or other sealing layer 140, as well as embodiments of threaded fasteners described.

While dimensions and other details of features are shown in FIGS. 3A-3D, variations of the system 100 can include other suitable ranges of dimension (e.g., with proper scaling, in relation to fluid dynamic aspects), as appropriate to providing desired fluid flow through the system 100.

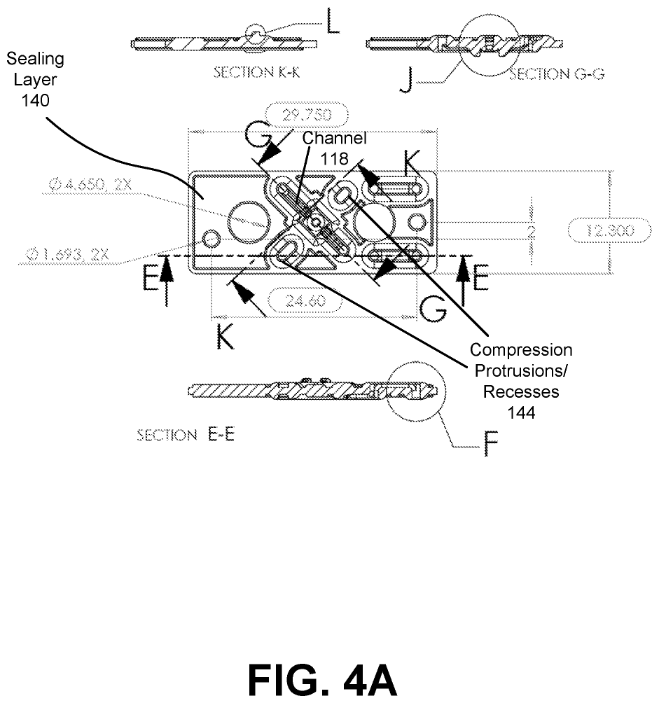

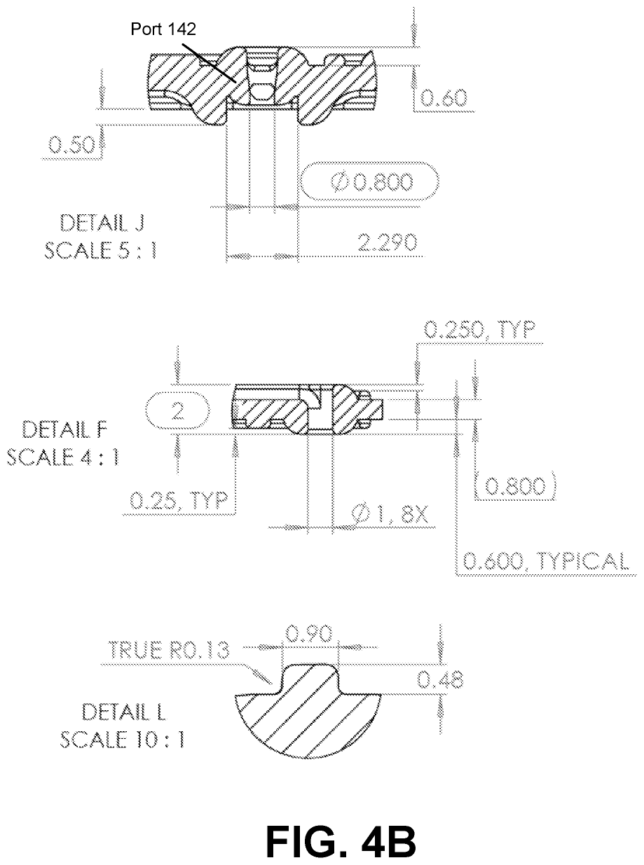

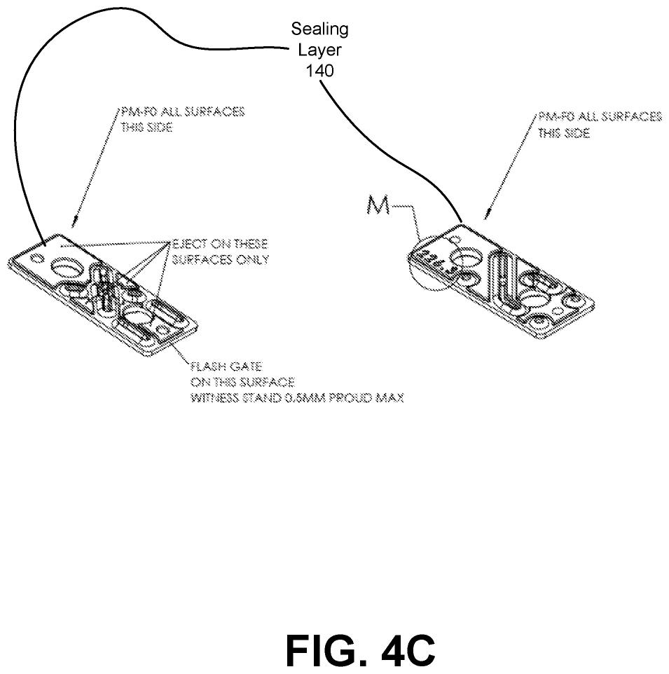

FIG. 4A depicts plan and cross-sectional views of a portion of the system (i.e., sealing layer 140) shown in FIG. 1. In particular, the sealing layer 140 includes recessed and protruding portions in details F, L, and J shown in cross-sectional views of FIG. 4B. In particular, detail F depicts a feature of the sealing layer 140 that prevents fluid leakage from the system 100, while promoting proper functioning of fluid driving through the system in coordination with application of desired voltages using the electrodes of the electrode layer 120. Detail J depicts a port 142 through the sealing layer 140 aligned with chip 130, where the port 142 includes protruding and recessed surfaces that promote proper sealing with chip 130. Detail L depicts a protruding feature of the sealing layer 140, with morphology that provides proper sealing in relation to fluid movement through the system 100.

In order to encourage uniform channel geometry and uniform sealing, the embodiment shown in FIG. 4A further includes: mirrored features, such as compression protrusions/recesses 144, on either side of the sealing layer 140 create a uniform compression thickness along as much of the channel 118 length as possible. The compression protrusions/recesses may not be fluidically functional (e.g., they transport no fluid) but are mechanically functional.

FIG. 4C depicts isometric views and assembly notes associated with the sealing layer 140 shown in FIG. 4A.

While dimensions and other details of features are shown in FIGS. 4A-4C, variations of the system 100 can include other suitable ranges of dimension (e.g., with proper scaling, in relation to fluid dynamic aspects), as appropriate to providing desired fluid flow through the system 100.

FIG. 4D depicts fabrication notes associated with the system shown in FIG. 4A.

FIG. 5A depicts an exploded view of a device for sample processing, including an apparatus 200 that supports and processes signals generated by the system 100 in order to return outputs to a user or other operator. The apparatus 200 shown in FIG. 5A includes a cavity configured to receive a unit of the system 100 shown in FIG. 1, with electronics and fluid handling/delivery subsystems for enabling proper performance of the system.

FIG. 5B depicts interaction between embodiments of components shown in FIGS. 1 and 5A, as described above.

Variations of the system 100 can include other suitable elements. An example method for manufacturing an embodiment of the system described above is provided below:

### Solid State Nanopore System Manufacturing and Preparation Prior to Use

In an example of a method for manufacturing an embodiment of the system 100 described above, the base substrate 110 and the second substrate 150 were injection molded in clear Polycarbonate. The sealing layer 140 was injection molded with an elastomer (e.g., 211-45 Santoprene™). The electrodes were then screen-printed using Ag/AgCl ink on 5 mil PET sheeting with an anti-abrasive carbon coating on the connecting ends of electrodes. Prior to assembly, polycarbonate and elastomer parts were cleaned (e.g., with 99.5% isopropyl alcohol) in an ultrasonic cleaner for a duration of time (e.g., 3 minutes), flushed with deionized (DI) water, and dried (e.g., at ambient temperature). The chip 130 and channels were sealed by compression of the sealing layer 140, by tightening of the set of fasteners 160a, 160b (e.g., screws passing through the base substrate 110, the second substrate 150, and the sealing layer 140 were tightened onto nuts with a calibrated torque screwdriver for even compression of the seal to 25%) in order to ensure leak-free sealing such that electrical conductivity between the channels can occur only through the nanopore 133.

Prior to reagent testing, assembled units of the system 100 were prepared as follows. Units of the system (i.e., test strips) were filled with 10 uL of buffer in both the cis and trans channels, and the strips were loaded into a custom voltage-clamped amplifier. Square voltage pulses 0.2 s in duration and ranging from ±2V to ±12V in magnitude were used to incentivize nanopore wetting. Following wetting, nanopore fitness was assessed by the symmetry of conductance over a voltage sweep from −0.3V to 0.3V, and by the root-mean-square of the current (IRMS) at 0.1 V. Pores with asymmetry <10% and IRMS <30 pA were used for reagent testing. Nanopore sizes estimated from the current ranged from 25-35 nm at the start of reagent testing. Nanopores grew up to 40 nm in diameter in some cases during the process of reagent testing, for a total diameter range of 25-40 nm across all data provided in the paper.

### CONCLUSIONS

Embodiments of the system(s) described can include or otherwise be used in coordination with systems (e.g., nanopore elements) described in U.S. application Ser. No. 16/083,997 (now issued as U.S. Pat. No. 10,488,394) titled “Wafer-Scale Assembly of Insulator-Membrane-Insulator Devices for Nanopore Sensing” and filed on Mar. 20, 2017, and U.S. application Ser. No. 16/009,007 titled “Dual Pore—control and sensor device” and filed on Jun. 14, 2018, which are each herein incorporated in its entirety by this reference.

### ADDITIONAL CONSIDERATIONS

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Some portions of this description describe the embodiments of the invention in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product including a computer-readable non-transitory medium containing computer program code, which can be executed by a computer processor for performing any or all of the steps, operations, or processes described.

Embodiments of the invention may also relate to a product that is produced by a computing process described herein. Such a product may include information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

What is claimed is:

1. A system for processing a sample, the system comprising:
a base substrate;
an electrode layer configured to route one or more electrodes for voltage application;
a chip retained within a cavity of the base substrate and in electrical communication with the electrode layer;
a sealing layer, the electrode layer positioned between the sealing layer and the base substrate;
a second substrate, the sealing layer positioned between the second substrate and at least a portion of the electrode layer and the base substrate; and
a set of fasteners compressing the sealing layer, the electrode layer, and the chip between the second substrate and the base substrate.

2. The system of claim 1, wherein the electrode layer comprises a set of electrodes comprising a conductive ink printed onto a polymer base, with an anti-abrasive coating at connecting ends of the set of electrodes.

3. The system of claim 1, wherein the chip comprises a membrane composed of silicone nitride coupled to a semiconducting substrate, and a nanopore defined within the membrane, the nanopore having a diameter from 25-35 nm.

4. The system of claim 3, wherein the chip further comprises an insulating layer configured to reduce noise associated with molecules passing into the nanopore, the membrane retained in position between the insulating layer and the semiconducting substrate.

5. The system of claim 1, further comprising a fluidic network with one or more channels defined within at least one of the base substrate, the chip, the sealing layer, and the second substrate.

6. The system of claim 5, wherein the sealing layer is compressed between the base substrate and the second substrate, thereby preventing fluid escape from and air ingress into the fluidic network during operation.

7. The system of claim 5, wherein at least one of the one or more channels crosses over boundaries between the electrode layer and the base substrate, thereby providing a continuity in sealing interfaces between the second substrate, the base substrate, and the electrode layer.

8. The system of claim 5, wherein each of the one or more channels has a volumetric capacity from 2 to 20 microliters.

9. The system of claim 5, further comprising a set of flow redirectors positioned about a microwell side of the chip and an etch pit side of the chip, the set of flow redirectors comprising curved channel morphologies configured to direct bubble-free fluid toward and away from a microwell of the chip.

10. The system of claim 5, wherein the sealing layer comprises a protrusion into a side of the chip comprising the nanopore, the protrusion reducing surface area for buffer contact at the nanopore.

11. The system of claim 5, wherein the sealing layer comprises at least one of a set of protrusions and a set of recesses mirrored about a channel of the fluidic network, thereby promoting uniform compressing along the channel.

12. The system of claim 1, wherein the sealing layer is composed of an elastomer.

13. The system of claim 1, wherein the base substrate comprises a first end defining a depression configured for handling by an operator, and a second end coupled to a bumper, the bumper configured to lift couplers of a complementary apparatus and position them into alignment with the electrode layer.

14. The system of claim 1, wherein the sample comprises single molecules comprising one or more of: DNA, RNA, polymers, and proteins.

15. The system of claim 1, wherein the system comprises operation modes for molecular quantification, sizing, and characterization of one or more molecules of the sample.

16. The system of claim 1, wherein the system comprises operation modes for characterization of macromolecular interactions between two or more molecules of the sample.

17. A system for processing a sample, the system comprising:
a base substrate;
an electrode layer comprising conductive ink patterned onto a polymer substrate;
a chip retained within a cavity of the base substrate and in electrical communication with the electrode layer, the chip surrounded by a set of flow redirectors configured to prevent bubbles from entering the chip;
a sealing layer, wherein the sealing layer comprises a protrusion toward the chip and wherein the electrode layer is positioned between the sealing layer and the base substrate;
a second substrate, the sealing layer positioned between the second substrate and at least a portion of the electrode layer and the base substrate; and
a set of fasteners compressing the sealing layer, the electrode layer, and the chip between the second substrate and the base substrate,
wherein the system comprises a fluidic network comprising one or more channels defined within the base substrate, the sealing layer, the chip, and the second substrate.

18. The system of claim 17, wherein at least one of the one or more channels crosses over boundaries between the electrode layer and the base substrate, thereby providing a continuity in sealing interfaces between the second substrate, the base substrate, and the electrode layer.

19. The system of claim 17, wherein the chip comprises a membrane composed of silicone nitride coupled to a semiconducting substrate, and a nanopore defined within the membrane, wherein the chip further comprises an insulating layer configured to reduce noise associated with molecules passing into the nanopore, and wherein the membrane is retained in position between the insulating layer and the semiconducting substrate.

20. The system of claim 17, wherein the system comprises operation modes for molecular quantification, sizing, and characterization of one or more molecules of the sample, and wherein the system comprises operation modes for characterization of macromolecular interactions between two or more molecules of the sample.
